(19) United States
(12) Patent Application Publication
(10) Pub. No.: US 2026/0324429 A1
(43) Pub. Date: Oct. 15, 2026

(54) MANAGING HEAT DISSIPATION STRUCTURES

(71) Applicant: Yangtze Memory Technologies Co., Ltd., Wuhan (CN)

(72) Inventors: Luanluan XUE, Wuhan (CN); Dongyu FAN, Wuhan (CN); Hao ZHENG, Wuhan (CN); Lei LIU, Wuhan (CN)

(21) Appl. No.: 19/224,179

(22) Filed: May 30, 2025

(30) Foreign Application Priority Data
Apr. 15, 2025 (CN) 202510473351.2

(51) Int. Cl. H01L 23/427; H01L 21/48; H01L 23/00; H10B 41/20; H10B 43/20

(52) U.S. Cl. CPC H10W 40/73; H10W 70/023; H10B 41/20; H10B 43/20; H10W 72/073; H10W 72/07338; H10W 90/734; H10W 90/736

(57) ABSTRACT

The present disclosure relates to methods, devices, and systems for managing heat dissipation structures. As an example, a heat dissipation structure includes a substrate, and a microchannel formed in the substrate. The microchannel has pillar structures adjacent to and spaced from a surface of the microchannel, where the pillar structures are arranged along an extending direction of the microchannel.

### CROSS-REFERENCE TO RELATED APPLICATIONS

This application claims priority to Chinese Patent Application No. 202510473351.2, filed on Apr. 15, 2025, which is hereby incorporated by reference in its entirety.

### TECHNICAL FIELD

The present disclosure relates to heat dissipation structures and fabrication method thereof.

### BACKGROUND

As the complexity and computational power of chips increase, more heat may be generated during the operation of the chips. The efficiency of thermal management can impact the performance stability and long-term reliability of the chips.

### SUMMARY

The present disclosure describes methods, devices, systems, and techniques for managing heat dissipation structures.

One aspect of the present disclosure features a heat dissipation structure. The heat dissipation structure includes a substrate, and a microchannel formed in the substrate. The microchannel has pillar structures adjacent to and spaced from a surface of the microchannel, where the pillar structures are arranged along an extending direction of the microchannel.

In some implementations, a distance between a pillar structure and the surface is smaller than a distance between a center line of the microchannel and the surface.

In some implementations, the microchannel is configured such that, when a liquid coolant flows in the microchannel, the liquid coolant flows on a first side of the pillar structures, and a gas evaporated from the liquid coolant flows on a second side of the pillar structures. The first side of the pillar structures is closer to the surface of the microchannel than the second side of the pillar structures.

In some implementations, the microchannel includes one or more linear sub-channels.

In some implementations, the microchannel includes one or more annual sub-channels connected sequentially.

In some implementations, an annular sub-channel includes a Tesla micro valve having a first channel and a second channel. A first end of the first channel is coupled to a first end of the second channel, and a second end of the first channel is coupled to a second end of the second channel, where the second channel is a curved channel.

In some implementations, the pillar structures include a plurality of first pillar structures arranged in the first channel, and a plurality of second pillar structures arranged in the second channel.

In some implementations, an isolated part of the substrate is enclosed by the first channel and the second channel. The plurality of first pillar structures and the plurality of second pillar structures are arranged away from the isolated part.

In some implementations, a width of the first channel is approximately 200 μm, and a width of the second channel is approximately 100 μm.

In some implementations, a distance between a first pillar structure of the pillar structures and the surface is between 10 μm and 30 μm. Along the extending direction, a distance between the first pillar structure and a second pillar structure adjacent to the first pillar structure is less than 20 μm.

In some implementations, the pillar structures are cylinders, wherein a diameter of a cylinder is approximately 30 μm, and wherein a height of the cylinder is equal to a depth of the microchannel.

In some implementations, the substrate and the pillar structures comprise a same material that has a thermal conductivity greater than 100 W/m·K.

Another aspect of the present disclosure features a semiconductor device. The semiconductor device includes a first semiconductor structure including a memory array, a second semiconductor structure including a peripheral circuit coupled to the first semiconductor structure, and a heat dissipation structure. The heat dissipation structure includes a substrate, and a microchannel formed in the substrate. The microchannel includes pillar structures adjacent to and spaced from a surface of the microchannel, the pillar structures being arranged along an extending direction of the microchannel.

In some implementations, the second semiconductor structure is between the first semiconductor structure and the heat dissipation structure.

In some implementations, the heat dissipation structure is coupled to the second semiconductor structure by a thermal interface layer.

In some implementations, the semiconductor device comprises a NAND memory device.

In some implementations, the first semiconductor structure includes first conductive structures isolated by a first isolating material, and the second semiconductor structure includes second conductive structures isolated by a second isolating material. The first semiconductor structure and the second semiconductor structure are bonded together by the first conductive structures being in contact with the second conductive structures.

In some implementations, the heat dissipation structure includes one or more Tesla micro valves connected sequentially.

A further aspect of the present disclosure features a method of forming a heat dissipation structure. The method includes forming a microchannel in a substrate of the heat dissipation structure. The microchannel includes pillar structures adjacent to and spaced from a surface of the microchannel, the pillar structures being arranged along an extending direction of the microchannel.

In some implementations, the method includes forming a mask layer on the substrate, where the substrate includes a material having a thermal conductivity higher than a threshold; photoetching the mask layer to form a pattern in the mask layer, where the pattern corresponds to the microchannel comprising the pillar structures; and etching, based on the pattern in the mask layer, the substrate to form the heat dissipation structure.

In some implementations, the method further includes attaching the heat dissipation structure to one side of a chip by forming a thermal interface layer between the heat dissipation structure and the chip.

The details of one or more implementations of the subject matter of this present disclosure are set forth in the accompanying drawings and the description below. Other features, aspects, and advantages of the subject; matter will become apparent from the description, the drawings, and the claims.

### BRIEF DESCRIPTION OF DRAWINGS

FIG. 1 illustrates an example heat dissipation structure.

FIG. 2A illustrates an example Tesla micro valve.

FIGS. 2B-2C illustrate an example Tesla micro valve having pillar structures.

FIG. 3 illustrates an example flow in a microchannel having pillar structures.

FIGS. 4A-4B illustrate an example semiconductor structure having a heat dissipation structure.

FIGS. 5A-5B illustrate an example heat dissipation structure having linear sub-channels.

FIGS. 6A-6D illustrate an example process of forming a heat dissipation structure.

FIG. 7 illustrates an example process of forming a heat dissipation structure.

FIGS. 8A-8B illustrate example systems having heat dissipation structures.

Like reference numbers and designations in the various drawings indicate like elements. It is also to be understood that the various exemplary implementations shown in the figures are merely illustrative representations and are not necessarily drawn to scale.

### DETAILED DESCRIPTION

As the integration level of chips (e.g., memory chips, computing chips) becomes increasingly high, heat dissipation problems of the chips become increasingly serious. If heat generated from the chips cannot be dissipated effectively and timely, a high temperature may damage circuits in the chips, thereby affecting the working stability of the chips.

To dissipate heat generated by a chip, a heat dissipation structure can be attached to the chip. The heat dissipation structure can include microchannels, where a coolant can flow in the microchannels to take away heat. In some cases, the microchannels can include Tesla micro valves to achieve uni-directional flow control (e.g., accelerating forward flow and blocking reverse flow)). In some instances, boiling instability may occur when the coolant in the microchannels undergoes phase change. For example, the gas evaporated from the liquid coolant may block the pathway of the coolant such that the liquid coolant may not be replenished in a timely manner, which may lead to overheating of the chip and negatively impact the performance and reliability of the chip.

The present disclosure provides techniques to improve heat dissipation efficiency of heat dissipation structures. In some implementations, a microchannel of a heat dissipation structure can include pillar structures adjacent to and spaced from a surface of the microchannel. The pillar structures can be arranged along an extending direction of the microchannel. In some implementations, the pillar structures can be arranged close to one another and close to the surface of the microchannel, so that the capillary effect of the pillar structures can separate the liquid pathway from the gas pathway in the microchannel. For example, the liquid coolant can flow on one side of the pillar structures, and the gas evaporated from the liquid coolant can flow on the other side of the pillar structures, so that the liquid pathway may not be blocked by the gas.

Techniques of the present disclosure can provide one or more of the following technical advantages and/or benefits. For example, by separating the liquid pathway and the gas pathway in the microchannels of the heat dissipation structure, boiling instability issues can be reduced, which can improve heat dissipation efficiency and reduce the risk of overheating of the chip. For another example, compared to other solutions such as increasing the roughness of the inner walls of the microchannel to enhance nucleation sites, or suppressing the backflow of gas bubbles by designing pressure differentials, the disclosed techniques utilize pillar structures, which can be fabricated through a less complicated process. Further, manufacturing processes to achieve the disclosed techniques are compatible with existing processes to manufacture microchannels in the heat dissipation structure, and therefore cost-effective. In addition, the disclosed techniques do not require additional pressure differential control, which can reduce the size of the packaged chip, and can reduce energy consumption. In some implementations, different or more technical advantages may be achieved.

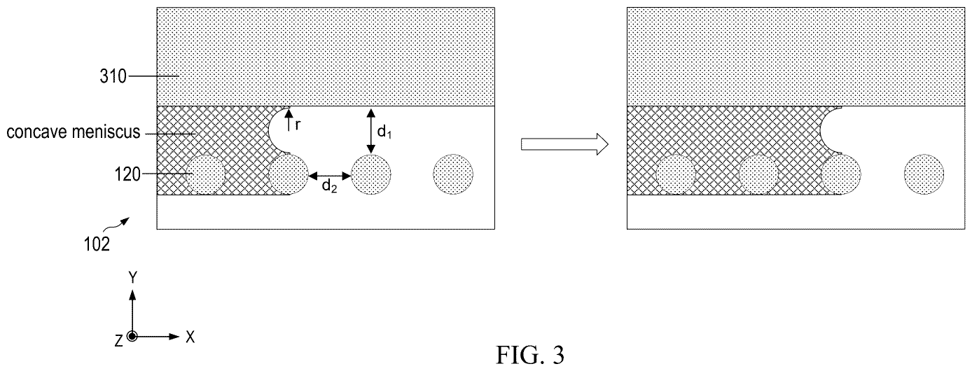

It is noted that X, Y, and Z axes (also referred to as X, Y, and Z directions) are included in FIG. 3 to further illustrate the spatial relationship of various components in a semiconductor device. A substrate of the semiconductor device can include two lateral surfaces extending laterally in the X-Y plane: a top surface on the front side of the substrate on which a component of the semiconductor device can be formed, and a bottom surface on the backside opposite to the front side of the substrate. Z direction is perpendicular to both the X and Y directions. As used in the present disclosure, whether one component (e.g., a layer or a device) is “on,” “above,” or “below” another component (e.g., a layer or a device) of the semiconductor device is determined relative to the substrate of the semiconductor device in Z direction (the vertical direction perpendicular to the X-Y plane, e.g., the thickness direction of the substrate) when the substrate is positioned in the lowest plane of the semiconductor device in Z direction. The same notion for describing the spatial relationships is applied throughout the present disclosure.

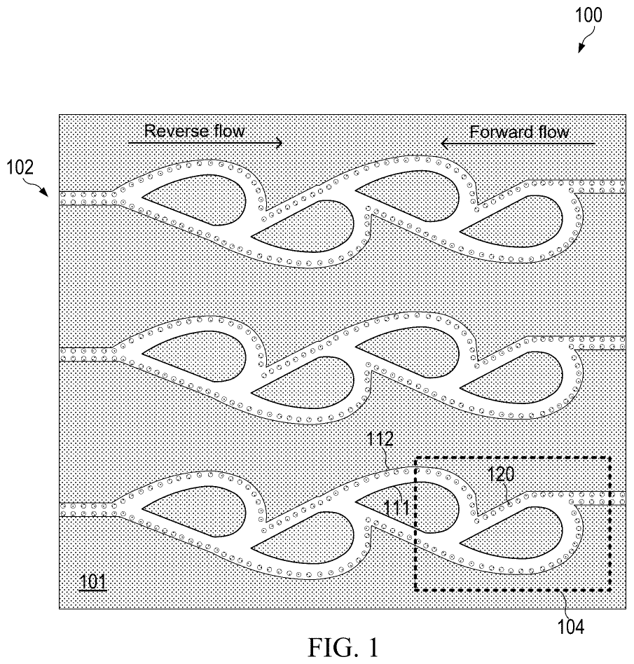

FIG. 1 illustrates an example heat dissipation structure 100. The heat dissipation structure 100 can include a substrate 101 and one or more microchannels 102 formed in the substrate 101. As an example in FIG. 1, the microchannels 102 can be arranged in parallel and each have an inlet and an outlet. The substrate 101 can be made of a material having high thermal conductivity, e.g., having a thermal conductivity greater than 100 W/m·K. For example, the substrate 101 can be made of metal (e.g., aluminum, copper) or metal compound, ceramic material (e.g., AlN), carbon-based materials (e.g., graphene), and/or any suitable material.

In some implementations, a coolant can flow in the microchannels 102 to take away heat dissipated by a device (e.g., a chip, a battery cell, etc.) attached to the heat dissipation structure 100. For example, when the temperature exceeds a certain threshold, the coolant in liquid form may evaporate into gas form, which can further take away heat dissipated by the attached device. Example coolants can include water, acetone, fluorinated liquid, or any suitable material having high heat capacity and/or low boiling point.

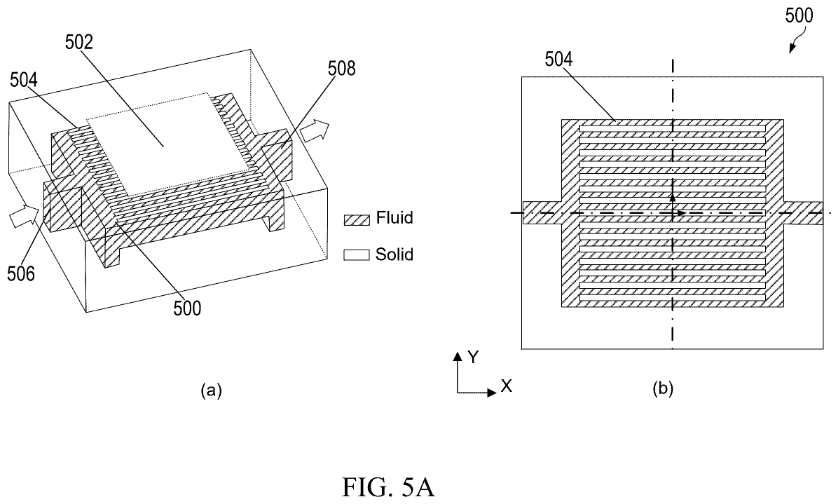

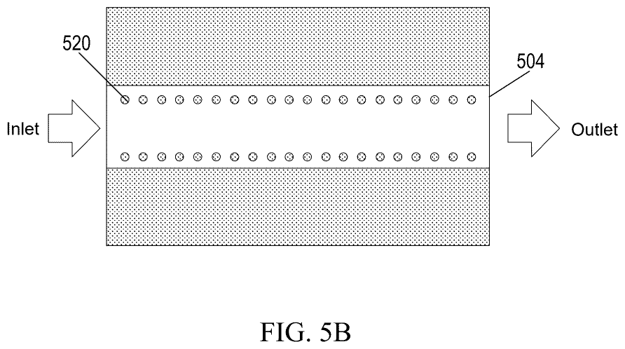

In some implementations, each microchannel 102 of the heat dissipation structure 100 can include one or more linear sub-channels, as explained with reference to FIGS. 5A-5B. In some implementations, each microchannel 102 of the heat dissipation structure 100 can include one or more annular sub-channels connected sequentially, e.g., from an inlet of the microchannel 102 to an outlet of the microchannel 102. In some implementations, each annular sub-channel can be a Tesla micro valve 104. In other words, a microchannel 102 can include one or more Tesla micro valves 104 connected sequentially. The Tesla micro valves 104 can utilize an asymmetrical geometric configuration to control the flow direction. For instance, when a fluid moves forward in the Tesla micro valves 104, the fluid splits into two streams at each junction, and can smoothly merge back together in the next section, speeding up the flow with minimal friction. However, if the fluid flows reversely in the Tesla micro valves 104, the split streams collide with each other at the next junction, which increases resistance that can slow or stop the flow. As such, the Tesla micro valves 104 can be used to ensure a uni-directional flow in the microchannel 102.

In some implementations, as shown in FIG. 1, each microchannel 102 can include pillar structures 120 arranged along a surface of the microchannel 102. The pillar structures 120 can be capillary micropillar structures (e.g., having sizes smaller than 100 μm) that are spaced from each other along an extending direction of the microchannel 102. As shown in FIG. 1, the microchannel 102 having Tesla micro valves 104 connected in sequence can have an inner-side surface 111 that is non-consecutive, and an outer-side surface 112 that is consecutive. In some implementations, the pillar structures 120 can be arranged adjacent to and spaced from the outer-side surface 112 of the microchannel 102. The pillar structures 120 can be arranged closer to the outer-side surface 112 than to the inner-side surface 111. For example, a distance between a pillar structure and the outer-side surface 112 can be smaller than a distance between a center line (e.g., a line having equal distances to the inner-side surface 111 and to the outer-side surface 112) of the microchannel 102 and the outer-side surface 112.

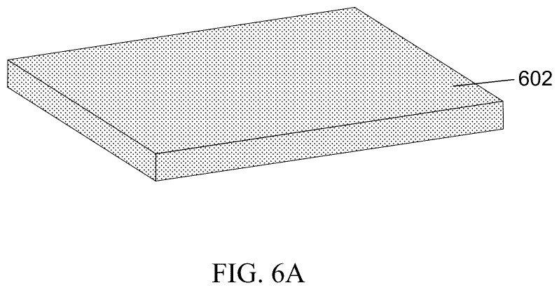

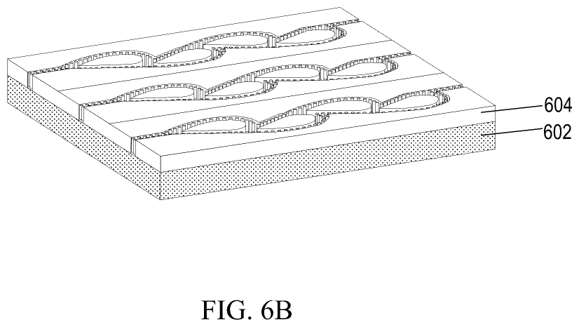

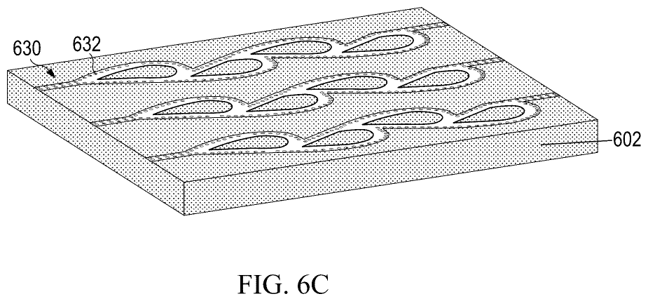

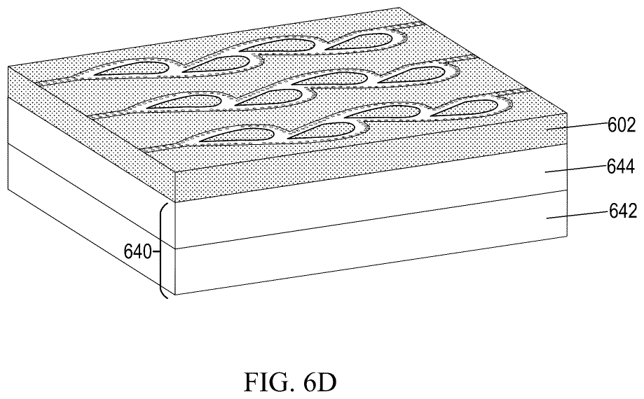

In some implementations, the pillar structures 120 can have the same material as the substrate 101. In some implementations, as illustrated with reference to FIGS. 6A-6C, the pillar structures 120 can be formed based on portions of the substrate 101 retained after etching.

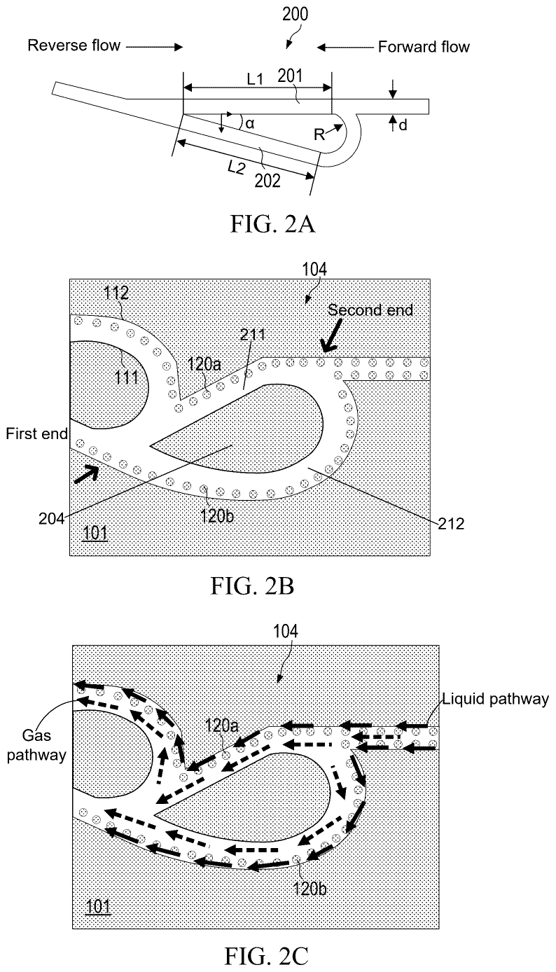

FIG. 2A illustrates an example Tesla micro valve 200. The Tesla micro valve 200 can include a first channel 201 and a second channel 202 in communication with each other. The unidirectional flow efficiency of the Tesla micro valve 200 can be quantified by a metric “diodicity”. In some cases, diodicity of the Tesla micro valve 200 can be defined as the ratio of the pressure drop of reverse flow to the pressure drop of forward flow:

$$Diodicity = \frac{Δ {P}_{r}}{Δ {P}_{f}} = \frac{{P}_{r . , in} - {P}_{r , out}}{{P}_{f , i n} - {P}_{f , out}}$$

A higher diodicity value can indicate better flow rectification and a greater tendency towards forward flow in the Tesla micro valve 200. The diodicity of the Tesla micro valve 200 may depend on geometric parameters of the Tesla micro valve 200, including an angle (α) between the first channel 201 and the second channel 202, a radius (R) of a curved portion of the second channel 202, a width (d) of the channels 201, 202, and a height (H) of the channels 201, 202. In some cases, when a is smaller, R can be smaller, and diodicity can be greater; and when the ratio of H to dis close to 0.35, the diodicity may be optimal. However, in practical applications, a being too small may complicate fabrication and compromise structural integrity, hence a can be in the range of 15°-30°. In some cases, while increasing H with fixed d may slightly reduce diodicity, it can increase the flow throughput, which may enhance heat dissipation performance. Thus, in practical applications, H/d ratio can be up to 1:1 or slightly higher.

FIGS. 2B-2C illustrate an example Tesla micro valve 104 having pillar structures 120. As shown in FIG. 2B, the Tesla micro valve 104 can have a first channel 211 and a second channel 212 in communication with each other. A first end of the first channel 211 can be coupled to a first end of the second channel 212, and a second end of the first channel 211 can be coupled to a second end of the second channel 212. An isolated part 204 of the substrate 101 is enclosed by the first channel 211 and the second channel 212. In some implementations, the first channel 211 can be a linear channel, and the second channel 212 can be a curved channel. In some other implementations, the first channel 211 and the second channel 212 can be curved channels having different curvatures.

In some implementations, the first channel 211 can have a greater width than the second channel 212. As an example, a width of the first channel 211 can be approximately 200 μm, and a width of the second channel 212 can be approximately 100 μm. In some other implementations, the first channel 211 and the second channel 212 can have the same width, or substantially the same width,

In some implementations, the microchannel 102 has first pillar structures 120a arranged in the first channel 211 of the Tesla micro valve 104, and second pillar structures 120b arranged in the second channel 212 of the Tesla micro valve 104. The first pillar structures 120a can be arranged adjacent to an outer-side surface of the first channel 211, e.g., away from the isolated part 204. The second pillar structures 120b can be arranged adjacent to an outer-side surface of the second channel 212, e.g., away from the isolated part 204.

As shown in FIG. 2C, by having the pillar structures 120 (including 120a and 120b) in the microchannel, liquid coolant and a gas evaporated from the liquid coolant can flow in different pathways. For example, due to the capillary effect of the pillar structures 120, the liquid coolant can flow on a first side of the pillar structures 120 (e.g., be confined between the outer-side surface 112 and the pillar structures 120, and the gas evaporated from the liquid coolant can flow on a second side of the pillar structures 120 (e.g., be confined between the inner-sider surface 111 and the pillar structures 120). In some implementations, the first side of the pillar structures 120 is closer to the outer-side surface 112 of the microchannel 102 than the second side of the pillar structures 120. As such, by separating liquid and gas pathways, the microchannel 102 can suppress boiling instability caused by vapor-liquid interference during cooling.

FIG. 3 illustrates an example flow in a microchannel 102 having pillar structures 120. The capillary effect of the pillar structures 120 can depend on the geometric configuration of the pillar structures 120. For ease of illustration, suppose that the sidewall 310 (e.g., outer-side surface 112 of FIG. 2B) of the microchannel 102 is a super-hydrophilic surface (contact angle≈0°), the liquid between the sidewall 310 and the pillar structure 120 can form a concave meniscus. The radius (r) of the concave meniscus can be r=d₁/2, where d₁ is the distance between the sidewall 310 and the pillar structures 120. The Laplace pressure difference (Δp) of the concave meniscus can be expressed as

$$Δ p = γ ( \frac{1}{r} ) ,$$

where γ is the surface tension factor of the liquid coolant in the microchannel 102.

The Laplace pressure difference can drive the liquid coolant to flow forward between the sidewall 310 and the pillar structures 120, forming a continuous liquid film. During phase change of the liquid coolant, the gas evaporated from the liquid coolant flows on the other side of the pillar structures 120. As such, the liquid pathway can be confined to one side of the pillar structures 120 and the gas pathway can be confined to the other side of the pillar structures 120, which can reduce boiling instability. In comparison, without having the pillar structures, the gas evaporated from the liquid coolant may block the liquid pathway, such that certain regions of the microchannel may be depleted with liquid coolant and therefore risk overheating. By having the pillar structures 120 to separate the liquid pathway and the gas pathway, liquid coolant can be rapidly replenished through the liquid pathway without gas interference, which can mitigate the risk of overheating.

In some cases, on the one hand, when d₁ is smaller, the Laplace pressure difference (Δp) can be greater, which can increase the flow driving force. On the other hand, when d is too small, the liquid throughput may be limited, which may reduce the heat dissipation effect. In some implementations, d₁ can be between 10 μm and 30 μm.

In some cases, decreasing the distance (d₂) between adjacent pillar structures 120 may increase the capillary effect, but may introduce fabrication challenges (e.g., pore clogging) and introduce marginal gains due to flow resistance saturation. In some implementations, the distance between adjacent pillar structures 120 can be less than or equal to 20 μm, e.g., between 5 μm and 15 μm.

In some implementations, to achieve the capillary effect of the pillar structures, the width (e.g., measured along Y direction) and the depth (e.g., measured along Z direction) of the microchannel 102 need to be on the hundred-micron scale, while the diameter of the pillar structures 120 (e.g., cylinders), the distance (d₂) between adjacent pillar structures 120, and the distance (d₁) between the pillar structures 120 and the sidewall 310 need to range from hundreds of nanometers to tens of microns. As an example, the width of the microchannel 102 can be 200 μm, the depth of the microchannel 102 can be 250 μm, the diameter of the pillar structures 120 can be 30 μm, d₁ can be 15 μm, and d₂ can be 10 μm. The height of the pillar structures 120 can be equal to the depth of the microchannel 102. It should be noted that the microchannel 102 and the pillar structures 120 can have other geometric parameters as suited.

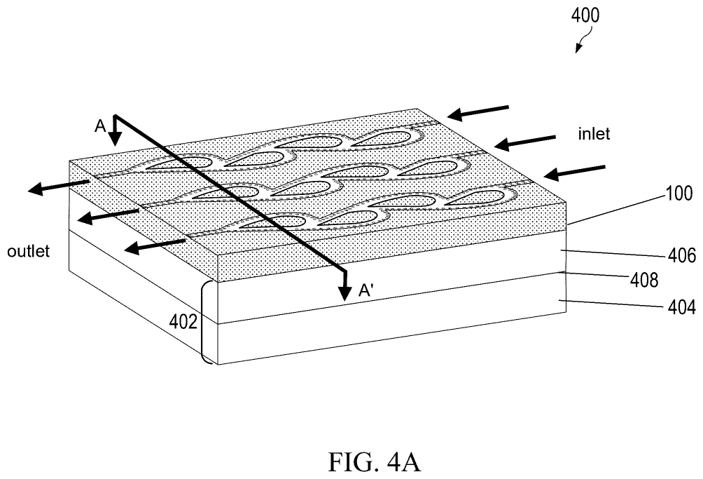

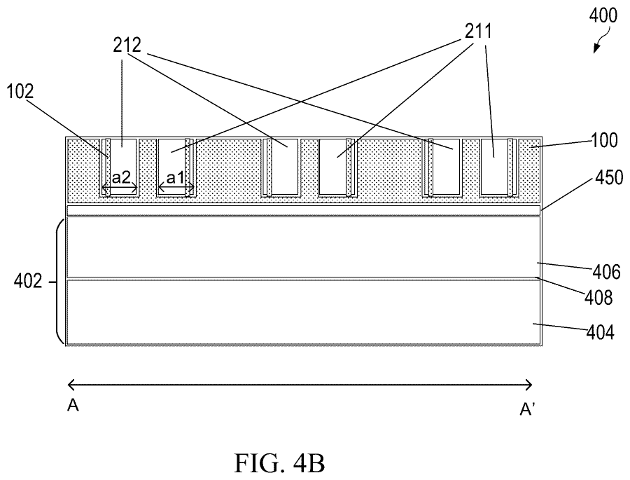

FIGS. 4A-4B illustrate an example semiconductor device 400 having a heat dissipation structure 100. As shown in FIG. 4A, the heat dissipation structure 100 can have an inlet where a coolant flows into the microchannels of the heat dissipation structure 100, and an outlet where the coolant flows out of the microchannels. In some implementations, the microchannels of the heat dissipation structure 100 include Tesla micro valves 104, and the inlet and the outlet of the microchannels can be configured according to the direction of forward flow of the Tesla micro valves 104.

In some implementations, the heat dissipation structure 100 can be coupled to a memory device 402 (e.g., a 3D memory device). In some implementations, the heat dissipation structure 100 can have the same, or substantially the same planar size as the memory device 402.

The memory device 402 can be a bonded chip, where components of the memory device (e.g., memory array and peripheral circuits) can be formed separately on different substrates and then joined to form the bonded chip. The memory device 402 can include a first semiconductor structure 404 including an array of memory cells (i.e., memory array). In some implementations, the memory array includes an array of NAND Flash memory cells. For ease of description, a NAND Flash memory array may be used as an example for describing the memory array in the present disclosure. But it is understood that the memory array is not limited to NAND Flash memory array and may include any other suitable types of memory arrays, such as dynamic random access memory (DRAM) cell array, static random access memory (SRAM) cell array, NOR Flash memory array, phase change memory (PCM) cell array, resistive memory array, magnetic memory array, spin transfer torque (STT) memory array, to name a few, or any combination thereof.

In some implementations, the memory device 402 can be a NAND Flash memory device in which memory cells are provided in the form of an array of 3D NAND memory strings and/or an array of two-dimensional (2D) NAND memory cells. NAND memory cells can be organized into pages or fingers, which are then organized into blocks in which each NAND memory cell is electrically connected to a separate line called a bit line (BL). All cells with the same vertical position in the NAND memory block can be electrically connected through the control gates by a word line (WL). In some implementations, a plane contains a certain number of blocks that are electrically connected through the same bit line. The first semiconductor structure 404 can include one or more planes, and the peripheral circuits that are needed to perform all the read/program (write)/erase operations can be included in the second semiconductor structure 406.

In some implementations, the array of NAND memory cells is an array of 2D NAND memory cells, each of which includes a floating-gate transistor. The array of 2D NAND memory cells include a plurality of 2D NAND memory strings, each of which includes a plurality of memory cells (e.g., 32 to 128 memory cells) connected in series (resembling a NAND gate) and two select transistors, according to some implementations. Each 2D NAND memory string is arranged in the same plane on the substrate (in 2D), according to some implementations. In some implementations, the array of NAND memory cells is an array of 3D NAND memory strings, each of which extends vertically above the substrate (in 3D) through a stack structure, e.g., a memory stack. Depending on the 3D NAND technology (e.g., the number of layers/tiers in the memory stack), a 3D NAND memory string typically includes 32 to 256 NAND memory cells, each of which includes a floating-gate transistor or a charge-trap transistor.

As shown in FIG. 4A, the memory device 402 can also include the second semiconductor structure 406 including the peripheral circuits of the memory array of the first semiconductor structure 404. The peripheral circuits (a.k.a. control and sensing circuits) can include any suitable digital, analog, and/or mixed-signal circuits used for facilitating the operations of the memory array. For example, the peripheral circuit can include one or more of a page buffer, a decoder (e.g., a row decoder and a column decoder), a sense amplifier, a driver (e.g., a word line driver), an I/O circuit, a charge pump, a voltage source or generator, a current or voltage reference, any portions (e.g., a sub-circuit) of the functional circuits mentioned above, or any active or passive components of the circuit (e.g., transistors, diodes, resistors, or capacitors). The peripheral circuits in second semiconductor structure 406 can use CMOS technology, e.g., which can be implemented with logic processes (e.g., technology nodes of 90 nm, 65 nm, 60 nm, 45 nm, 32 nm, 28 nm, etc.). As described above and below in detail, consistent with the scope of the present disclosure, the technology nodes used for fabricating the peripheral circuits in second semiconductor structure 406 are above 22 nm in order to reduce leakage current, maintain certain voltage levels (e.g., 1.2 V and above), and reduce the cost.

As shown in FIG. 4A, the memory device 402 further includes a bonding interface 408 between the first semiconductor structure 404 and the second semiconductor structure 406. In some implementations, the first and the second semiconductor structures 404 and 406 can be fabricated separately (and in parallel in some implementations) such that the thermal budget of fabricating one of first and second semiconductor structures 404 and 406 does not limit the processes of fabricating another one of first and second semiconductor structures 404 and 406. Moreover, a large number of interconnects can be formed through bonding interface 408 to make direct, short-distance (e.g., micron-level) electrical connections between first semiconductor structure 404 and second semiconductor structure 406, as opposed to the long-distance (e.g., millimeter or centimeter-level) chip-to-chip data bus on the circuit board, such as printed circuit board (PCB), thereby eliminating chip interface delay and achieving high-speed I/O throughput with reduced power consumption. Data transfer between the memory array in first semiconductor structure 404 and the peripheral circuits in second semiconductor structure 406 can be performed through the interconnects across the bonding interface 408. By vertically (e.g., along Z direction) integrating first and second semiconductor structures 404 and 406, the chip size can be reduced, and the memory cell density can be increased.

In some implementations, the first semiconductor structure 404 and the second semiconductor structure 406 can be bonded together by hybrid bonding, also known as “metal/dielectric hybrid bonding,” which is a direct bonding technology (e.g., forming bonding between surfaces without using intermediate layers, such as solder or adhesives) and can obtain metal-metal (e.g., Cu-to-Cu) bonding and dielectric-dielectric (e.g., SiO₂-to-SiO₂) bonding simultaneously. Data transfer between the memory array in the first semiconductor structure 404 and the peripheral circuits in the second semiconductor structure 406 can be performed through the interconnects across bonding interface 408. In some implementations, the bonding interface 408 can include a first bonding layer in the first semiconductor structure 404 and a second bonding layer in the second semiconductor structure 406. The first bonding layer can include first conductive structures isolated by a first isolating material (e.g., SiO₂ or other dielectric material). The second bonding layer can include second conductive structures isolated by a second isolating material (e.g., SiO₂ or other dielectric material). The first isolating material and the second isolating material can be the same or different, e.g., according to actual fabrication needs. Each of the second conductive structures can correspond to a first conductive structure of the first conductive structures. As such, when the first semiconductor structure 404 and the second semiconductor structure 406 are stacked together, the second conductive structures can be in contact with the corresponding first conductive structures to form conductive bonding (e.g., metal-to-metal bonding) through the bonding interface 408.

FIG. 4B illustrates a cross-sectional view of the semiconductor device 400 along cut line AA′ of FIG. 4A. As an example shown in FIG. 4B, the heat dissipation structure 100 can include three microchannels, and each microchannel can include Tesla micro valves having a first channel 211 and a second channel 212. In some implementations, a width (a₁) of the first channel 211 can be the same as a width (a₂) of the second channel 212. In some other implementations, a₁ and a₂ can be different, for example, a₁>a₂.

As shown in FIG. 4B, the heat dissipation structure 100 can be attached to the memory device 402 through a thermal interface layer 450. The thermal interface layer 450 can include a thermal interface material (TIM) to fill air gaps between the memory device 402 and the heat dissipation structure 100, so that the heat dissipation efficiency can be increased. The thermal interface layer 450 can include one or more of conductive silicone grease (which are cost-effective and easy to apply, but have relatively low thermal conductivity and may degrade under thermal cycling), thermal pads (easy to install, stable, but less adaptable due to thickness and shape), metal-based TIMs (e.g., metallic pastes made of Au, Cu, or Al nanoparticle suspensions, liquid metals such as Ga, GaIn, GaInSn); carbon-based TIMs (e.g., graphene-carbon nanotube aerogels, graphene foams, carbon films) and/or polymer-based TIMs (e.g., such as polydimethylsiloxane (PDMS) composites reinforced with graphite nanoplatelets or metallic fillers).

In some implementations, thermal grease and thermal pads can be directly applied or bonded at room temperature, offering quick and easy implementation. In some implementations, when using liquid metal as TIM, liquid metal can also be applied at room temperature, providing high thermal conductivity with minimal setup requirements. In some implementations, when using PDMS-based material as TIM, PDMS-based material can be filled between the memory device 402 and the heat dissipation structure 100 by capillary infiltration at room temperature, which is followed by thermal curing (e.g., at approximately 100° C.), to form a stable thermal connection.

In some implementations, the heat dissipation structure 100 is attached to the second semiconductor structure 406, since the peripheral circuits in the second semiconductor structure 406 may dissipate more heat than the memory array in the first semiconductor structure 404. As shown in FIG. 4B, the heat dissipation structure 100 is coupled to the second semiconductor structure 406 by the thermal interface layer 450, and the second semiconductor structure 406 is arranged between the first semiconductor structure 404 and the heat dissipation structure 100. In some implementations, the semiconductor device 400 may include another heat dissipation structure (not shown in FIG. 4B) attached to the first semiconductor structure 404 to take away heat dissipated from the first semiconductor structure 404.

FIGS. 5A-5B illustrate an example heat dissipation structure 500 having linear sub-channels 504. The heat dissipation structure 500 can be attached to a chip 502 to take away heat dissipated from the chip 502. In some implementations, the heat dissipation structure 500 can be coupled to the chip 502 through a thermal interface layer (e.g., the thermal interface layer 450 of FIG. 4B). The heat dissipation structure 500 and the chip 502 can be further packaged together to form an integral assembly. As shown in FIG. 5A, the heat dissipation structure 500 can include a microchannel having a plurality linear sub-channels 504. The sub-channels 504 can be connected to an inlet 506 of the microchannel and an outlet 508 of the microchannel, so that a coolant can flow in the microchannel from the inlet 506 to the outlet 508. As shown in FIG. 5B, each sub-channel 504 can include pillar structures 520 adjacent to and spaced from a surface of the sub-channel 504, so that the liquid coolant can flow on the first side of the pillar structures 520, and the gas evaporated from the liquid coolant can flow on the second side of the pillar structures 520.

It should be noted that the heat dissipation structure 500 can have any suitable type of microchannels where the coolant can flow. For example, the heat dissipation structure 500 can include microchannels in linear, honeycomb, triple-serpentine, side-serpentine, snowflake-shaped, and/or spiderweb-like configurations.

FIGS. 6A-6D illustrate an example process of forming a heat dissipation structure, such as the heat dissipation structure 100 as illustrated in FIGS. 1-4B.

As shown in FIG. 6A, a substrate 602 is provided. The substrate 602 can include a material having high thermal conductivity, e.g., having a thermal conductivity greater than 100 W/m·K. For example, the substrate 602 can be made of metal (e.g., aluminum, copper) or metal compound, ceramic material (e.g., AlN), carbon-based materials (e.g., graphene), and/or any suitable material.

As shown in FIG. 6B, a mask layer 604 can be formed on the substrate 602. The mask layer 604 can be photoetched to form a pattern in the mask layer 604, where the pattern corresponds to one or more microchannels (e.g., microchannels 102 of FIG. 1) having pillar structures (e.g., pillar structures 120 of FIG. 1). For example, portions of the mask layer 604 that correspond to the pillar structures are retained, while portions of the mask layer 604 that correspond to the microchannels can be removed.

After forming the pattern in the mask layer 604, the substrate 602 can be etched based on the pattern in the mask layer 604. For example, portions of the substrate 602 that are exposed by the mask layer 604 can be etched to form the microchannels 630, while portions of the substrate 602 that are covered by the mask layer 604 can be retained to form the pillar structures 632 arranged along a surface of each microchannel 630. Example etching techniques to etch the substrate 602 include wet etching, dry etching, plasma etching, reactive ion etching, etc.

As shown in FIG. 6C, after etching the substrate 602 based on the pattern in the mask layer 604, the mask layer 604 can be removed. As such, a heat dissipation structure (e.g., the heat dissipation structure 100 of FIG. 1) with microchannel having pillar structures can be formed.

In some implementations, as shown in FIG. 6D, the heat dissipation structure can be coupled to a chip 640 to form a system with heat management capabilities. For example, the chip 640 can be a memory device in the form of a bonded chip. The chip 640 can include a first semiconductor structure 642 (e.g., the first semiconductor structure 404 of FIGS. 4A-4B) including a memory array, and a second semiconductor structure 644 (e.g., the second semiconductor structure 406 of FIGS. 4A-4B) including a peripheral circuit that controls the memory array. In some implementations, the heat dissipation structure can be coupled to the first semiconductor structure 642 or the second semiconductor structure 644 through a thermal interface layer.

Further, the microchannels 630 can be coupled to a coolant inlet and a coolant outlet, so that a coolant can flow into the microchannels and then out of the microchannels to take away heat dissipated from the chip 640. In some implementations, the microchannels 630 can include Tesla micro valves connected sequentially, and the coolant inlet and the coolant outlet can be set according to a forward flow direction of the Tesla micro valves.

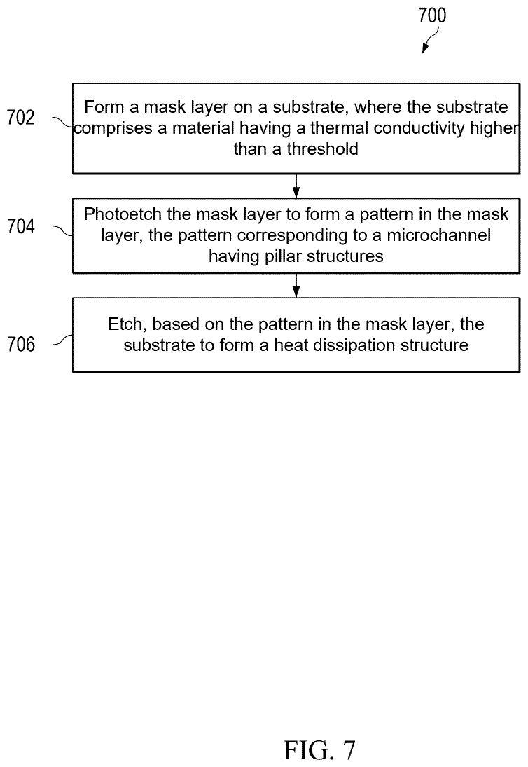

FIG. 7 illustrates an example process 700 of forming a heat dissipation structure, such as the heat dissipation structure 100 as illustrated in FIGS. 1-4B, or the heat dissipation structure formed by the substrate 602 as shown in FIG. 6C. The process 700 includes operations (or steps) that can be performed with any suitable order and/or any combination.

The process 700 can be implemented to form a microchannel (e.g., microchannel 102 of FIGS. 1-4B, microchannel 630 of FIG. 6C, or sub-channel 504 of FIGS. 5A-5B) in a substrate (e.g., substrate 602 of FIGS. 6A-6D) of the heat dissipation structure, where the microchannel includes pillar structures (e.g., pillar structures 120 of FIGS. 1-4B, pillar structures 520 of FIG. 5B, pillar structures 632 of FIG. 6C) adjacent to and spaced from a surface (e.g., outer-side surface 112 of FIG. 1) of the microchannel, the pillar structures being arranged along an extending direction of the microchannel.

At 702, a mask layer (e.g., mask layer 604 of FIG. 6B) is formed on a substrate (e.g., the substrate 602 of FIG. 6A), where the substrate comprises a material having a thermal conductivity higher than a threshold (e.g., 100 W/m·K).

At 704, the mask layer is photoetching to form a pattern in the mask layer, where the pattern corresponds to the microchannel including pillar structures, e.g., as shown in FIG. 6B.

At 706, the substrate is etched based on the pattern in the mask layer to form the heat dissipation structure. The heat dissipation structure includes one or more microchannels each having pillar structures. In some implementations, the capillary effect of the pillar structures can separate the liquid pathway and the gas pathway in the microchannel, such that a liquid coolant flows on a first side of the pillar structures, and a gas evaporated from the liquid coolant flows on a second side of the pillar structures.

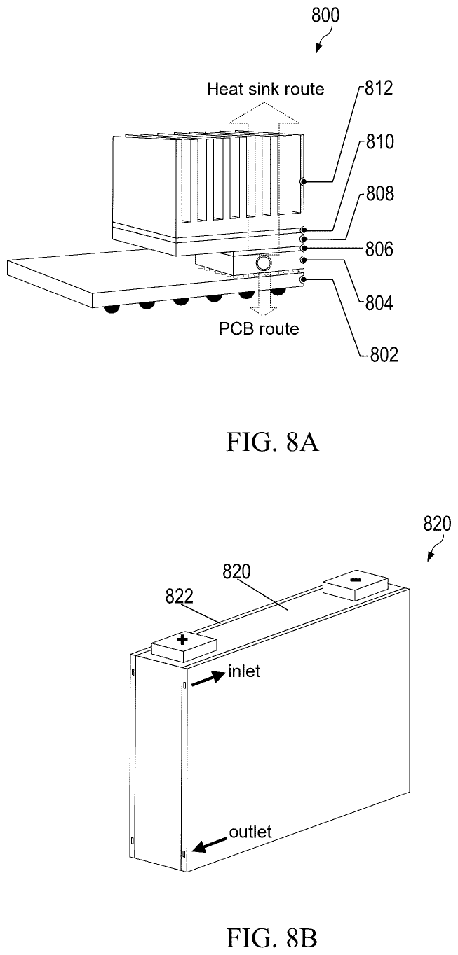

FIGS. 8A-8B illustrate example systems having heat dissipation structures (e.g., heat dissipation structure of FIGS. 1-4B, the heat dissipation structure of FIGS. 5A-5B). In some implementations, as shown in FIG. 8A, a heat dissipation structure (e.g., a heat dissipation plate) can be integrated into a general chip architecture 800. For example, in the general chip architecture 800, a chip 804 can be coupled to a printed circuit board (PCB) 802, e.g., through soldering, wire bonding, or other connection mechanisms. The chip 804 can be a memory chip (e.g., a NAND memory chip, or a DRAM memory chip), a computing chip (e.g., a central processor unit (CPU) chip, or a graphics processing unit (GPU) chip). The chip 804 can be coupled to a heat dissipation structure 808 through a thermal interface layer 806. In some implementations, the general chip architecture 800 can further include a heat sink 812. For example, the heat sink 812 can include fins to increase the surface area of the heat sink 812, so that heat can be more rapidly dissipated. In some implementations, a portion of the heat can be dissipated through the PCB 802, and a portion of the heat can be dissipated through the heat dissipation structure 808 and the heat sink 812.

In some implementations, as shown in FIG. 8B, a heat dissipation structure can be integrated into a battery system 820. The battery system 820 can include a battery cell 820 (e.g., a lithium-ion battery cell) having a positive terminal and a negative terminal. The battery cell 820 may generate a large amount of heat during charging and/or discharging. Heat dissipation structures 822 can be attached to surface of the battery cell 820, so that heat dissipated from the battery cell 820 can be taken away by a coolant that flows in the heat dissipation structures 822. It should be noted that heat dissipation structures can be included in other systems that need cooling and/or thermal management.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+ conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” or “approximately” can indicate a value of a given quantity that varies within, for example, 10-30% of the value (e.g., .+−. 10%, .+−. 20%, or .+−. 30% of the value). As used herein, the term “substantially” refers to a majority of, or mostly, as in at least about 50%, 60%, 70%, 80%, 90%, 95%, 96%, 97%, 98%, 99%, 99.5%, 99.9%, 99.99%, or at least about 99.999% or more.

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A heat dissipation structure, comprising:
a substrate; and
a microchannel formed in the substrate,
wherein the microchannel comprises pillar structures adjacent to and spaced from a surface of the microchannel, the pillar structures being arranged along an extending direction of the microchannel.

2. The heat dissipation structure of claim 1, wherein the microchannel is configured such that, when a liquid coolant flows in the microchannel, the liquid coolant flows on a first side of the pillar structures, and a gas evaporated from the liquid coolant flows on a second side of the pillar structures, and
wherein the first side of the pillar structures is closer to the surface of the microchannel than the second side of the pillar structures.

3. The heat dissipation structure of claim 1, wherein the microchannel comprises one or more linear sub-channels.

4. The heat dissipation structure of claim 1, wherein the microchannel comprises one or more annular sub-channels connected sequentially.

5. The heat dissipation structure of claim 4, wherein an annular sub-channel comprises a Tesla micro valve having a first channel and a second channel, and
wherein a first end of the first channel is coupled to a first end of the second channel, and a second end of the first channel is coupled to a second end of the second channel, and wherein the second channel is a curved channel.

6. The heat dissipation structure of claim 5, wherein the pillar structures comprise:
a plurality of first pillar structures arranged in the first channel; and
a plurality of second pillar structures arranged in the second channel.

7. The heat dissipation structure of claim 6, wherein an isolated part of the substrate is enclosed by the first channel and the second channel, and
wherein the plurality of first pillar structures and the plurality of second pillar structures are arranged away from the isolated part.

8. The heat dissipation structure of claim 5, wherein a width of the first channel is approximately 200 μm, and a width of the second channel is approximately 100 μm.

9. The heat dissipation structure of claim 1, wherein a distance between a first pillar structure of the pillar structures and the surface is between 10 μm and 30 μm, and
wherein, along the extending direction, a distance between the first pillar structure and a second pillar structure adjacent to the first pillar structure is less than 20 μm.

10. The heat dissipation structure of claim 1, wherein the pillar structures are cylinders, wherein a diameter of a cylinder is approximately 30 μm, and wherein a height of the cylinder is equal to a depth of the microchannel.

11. The heat dissipation structure of claim 1, wherein the substrate and the pillar structures comprise a same material that has a thermal conductivity greater than 100 W/m·K.

12. A semiconductor device, comprising:
a first semiconductor structure comprising a memory array;
a second semiconductor structure comprising a peripheral circuit coupled to the memory array; and
a heat dissipation structure comprising
a substrate; and
a microchannel formed in the substrate,
wherein the microchannel comprises pillar structures adjacent to and spaced from a surface of the microchannel, the pillar structures being arranged along an extending direction of the microchannel.

13. The semiconductor device of claim 12, wherein the second semiconductor structure is between the first semiconductor structure and the heat dissipation structure.

14. The semiconductor device of claim 13, wherein the heat dissipation structure is coupled to the second semiconductor structure by a thermal interface layer.

15. The semiconductor device of claim 12, wherein the semiconductor device comprises a NAND memory device.

16. The semiconductor device of claim 12, wherein the first semiconductor structure comprises first conductive structures isolated by a first isolating material, and the second semiconductor structure comprises second conductive structures isolated by a second isolating material, and
wherein the first semiconductor structure and the second semiconductor structure are bonded together by the first conductive structures being in contact with the second conductive structures.

17. The semiconductor device of claim 13, wherein the heat dissipation structure comprises one or more Tesla micro valves connected sequentially.

18. A method of forming a heat dissipation structure, comprising:
forming a microchannel in a substrate of the heat dissipation structure, wherein the microchannel comprises pillar structures adjacent to and spaced from a surface of the microchannel, the pillar structures being arranged along an extending direction of the microchannel.

19. The method of claim 18, comprising:
forming a mask layer on the substrate, wherein the substrate comprises a material that has a thermal conductivity higher than a threshold;
photoetching the mask layer to form a pattern in the mask layer, wherein the pattern corresponds to the microchannel comprising the pillar structures; and
etching, based on the pattern in the mask layer, the substrate to form the heat dissipation structure.

20. The method of claim 18, further comprising:
attaching the heat dissipation structure to one side of a chip by forming a thermal interface layer between the heat dissipation structure and the chip.
